(19) United States
(12) Patent Application Publication
(10) Pub. No.: US 2017/0253973 A1
(43) Pub. Date: Sep. 7, 2017

(54) SEMICONDUCTOR MANUFACTURING APPARATUS

(71) Applicant: KABUSHIKI KAISHA TOSHIBA, Minato-ku (JP)

(72) Inventor: Shinya TAGUCHI, Yokkaichi (JP)

(73) Assignee: KABUSHIKI KAISHA TOSHIBA, Minato-ku (JP)

(21) Appl. No.: 15/265,003

(22) Filed: Sep. 14, 2016

Related U.S. Application Data
(60) Provisional application No. 62/303,037, filed on Mar. 3, 2016.

(51) Int. Cl. C23C 16/50; H01J 37/32; C23C 16/455

(52) U.S. Cl. CPC C23C 16/50; C23C 16/455; H01J 37/32082; H01J 37/32532; H01J 2237/3321

(57) ABSTRACT

A semiconductor manufacturing apparatus includes a reactor, a first electrode, a second electrode, and a first member. The reactor can accommodate a semiconductor substrate therein. The first electrode can place the semiconductor substrate thereon. The second electrode is opposed to the first electrode. The first member supplies alternating-current power to the second electrode. The first member includes a conductor that is arranged on an outer circumferential surface or at an outer peripheral edge of the second electrode and that has an input/output end for the alternating-current power and a plurality of contacts with respect to the outer circumferential surface or the outer peripheral edge. The first member includes a plurality of passive elements each having a first input/output end and a second input/output end for the alternating-current power, where the first input/output end and the second input/output end are connected to different positions of the conductor.

### CROSS REFERENCE TO RELATED APPLICATIONS

This application is based upon and claims the benefit of priority from the prior U.S. Provisional Patent Application No. 62/303,037 filed on Mar. 3, 2016, the entire contents of which are incorporated herein by reference.

### FIELD

The embodiments of the present invention relate to a semiconductor manufacturing apparatus.

### BACKGROUND

In a film-forming process of a semiconductor device, in a state where a wafer is placed on a lower electrode inside a chamber, film-forming gas is supplied into the chamber from an upper electrode opposed to the lower electrode, that is, a showerhead electrode. By supplying high-frequency power between the lower electrode and the upper electrode in this state, the film-forming gas is turned into plasma to generate film-formation species. The film-formation species are deposited on a surface of the wafer to form a film.

In order to supply the high-frequency power, a power supply member that connects a high-frequency power source and the upper electrode to each other is provided in the upper electrode. The power supply member has a plurality of contacts between the upper electrode and supplies at each contact the high-frequency power from the high-frequency power source to the upper electrode.

However, conventional power supply members cannot achieve power supply that is uniform at the contacts. Therefore, it has been difficult to ensure uniformity of the film thickness in a plane of the wafer (hereinafter, the uniformity is also referred to as “in-plane uniformity”).

### BRIEF DESCRIPTION OF THE DRAWINGS

FIG. 1 is a schematic sectional view of a semiconductor manufacturing apparatus according to an embodiment;

FIG. 2 is a plan view of a power supply member in the semiconductor manufacturing apparatus according to the embodiment;

FIG. 3 is an equivalent circuit diagram of the power supply member in the semiconductor manufacturing apparatus according to the embodiment;

FIG. 4 is a diagram showing a setting example of capacitances of capacitors in the semiconductor manufacturing apparatus according to the embodiment;

FIG. 5 is a schematic diagram showing an adjustment of a combined impedance by the semiconductor manufacturing apparatus according to the embodiment;

FIG. 6 is an equivalent circuit diagram of a power supply member in a semiconductor manufacturing apparatus according to a first modification of the embodiment; and

FIG. 7 is a schematic sectional view showing a semiconductor manufacturing apparatus according to a second modification of the embodiment.

### DETAILED DESCRIPTION

A semiconductor manufacturing apparatus according to an embodiment includes a reactor, a first electrode, a second electrode, and a first member. The reactor can accommodate a semiconductor substrate therein. The first electrode is arranged in the reactor and can place the semiconductor substrate thereon. The second electrode is opposed to the first electrode in the reactor. The first member supplies alternating-current power to the second, electrode. The first member includes a conductor that is arranged on an outer circumferential surface or at an outer peripheral edge of the second electrode and that has an input/output end for the alternating-current power and a plurality of contacts with respect to the outer circumferential surface or the outer peripheral edge. The first member includes a plurality of passive elements each having a first input/output end and a second input/output end for the alternating-current power, where the first input/output end and the second input/output end are connected to different positions of the conductor.

Embodiments will now be explained with reference to the accompanying drawings. The present invention is not limited to the embodiments.

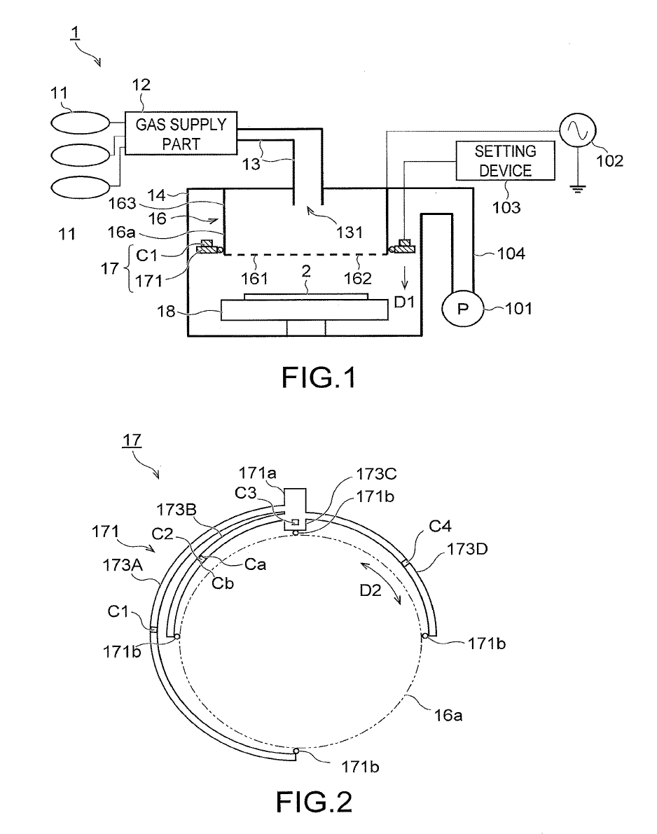

FIG. 1 is a schematic sectional view of a semiconductor manufacturing apparatus 1 according to the present embodiment. The semiconductor manufacturing apparatus 1 shown in FIG. 1 is a plasma CVD apparatus that is an example of a single-wafer CVD apparatus.

As shown in FIG. 1, the semiconductor manufacturing apparatus 1 includes a plurality of gas sources 11, a gas supply part 12, a gas introduction path 13, and a chamber 14 that is an example of a reactor, in this order from an upstream side of gas supply. Also, the semiconductor manufacturing apparatus 1 includes, inside the chamber 14, an upper electrode 16 that is an example of a second electrode, a power supply member 17 that is an example of a first member, and a lower electrode 18 that is an example of a first electrode, in this order from the upstream side of the gas supply. Further, the semiconductor manufacturing apparatus 1 includes a gas discharge path 104 and a pump 101 on a downstream side of the chamber 14. The semiconductor manufacturing apparatus 1 also includes a high-frequency power source 102 and a setting device 103.

The gas sources 11 accommodate therein, for example, material gas including a component of a film to be formed on a semiconductor substrate 2, that is, a wafer, and dilution gas of the material gas for facilitating generation of plasma.

The gas supply part 12 is connected to each of the gas sources 11 on a downstream side of the gas sources 11. The gas supply part 12 supplies gas in the gas sources 11 to the chamber 14 in accordance with a film-forming process. The gas supply part 12 can be configured by a mass flow controller or a valve, for example.

The gas introduction path 13 connects the gas supply part 12 and the chamber 14 to each other. Gas is introduced from the gas supply part 12 into the chamber 14 through the gas introduction path 13.

The chamber 14 can accommodate therein the semiconductor substrate 2, and can introduce thereinto the gas used for film formation on the semiconductor substrate 2.

The upper electrode 16, that is, a showerhead electrode surrounds a certain region including an outlet 131 of the gas introduction path 13 inside the chamber 14. The upper electrode 16 has a circular shape in a plan view. A bottom wall 161 of the upper electrode 16 has a plurality of through holes 162. The gas introduced into the chamber 14 is diffused by passing through the through holes 162. The diffused gas is supplied from the upper electrode 16 towards the semiconductor substrate 2.

The lower electrode 18 is arranged in a downward direction D1 of the upper electrode 16 inside the chamber 14. The lower electrode 18 has a circular shape in a plan view. The lower electrode 18 can place the semiconductor substrate 2 thereon. The semiconductor substrate 2 can have a circular shape in a plan view.

The lower electrode 18 has a heater incorporated therein and heats the semiconductor substrate 2 placed thereon by the heater to a predetermined temperature. By heating the semiconductor substrate 2, the film-formation rate can be increased.

The power supply member 17 is a member that supplies high-frequency power, that is, alternating-current power for causing generation of plasma between the upper electrode 16 and the lower electrode 18 to the upper electrode 16. The power supply member 17 can be also referred to as “RF (radio frequency) strap”.

The power supply member 17 is provided on an outer circumferential surface 16a of the upper electrode 16, that is, an outer surface of a side wall 163 of the upper electrode 16.

The power supply member 17 is connected to the high-frequency power source 102. The high-frequency power source 102 supplies the high-frequency power to the power supply member 17. The power supply member 17 supplies the high-frequency power supplied from the high-frequency power source 102 to the upper electrode 16. In this manner, the upper electrode 16 is coupled to the lower electrode 18 by capacity-coupling and supplies the high-frequency power into the chamber 14. The gas supplied into the chamber 14 in a vacuum state is turned into plasma (ionized) by the high-frequency power supplied into the chamber 14. Consequently, the chamber 14 is filled with plasma gas, so that a film is deposited on the semiconductor substrate 2.

The high-frequency power source 102, that is, the power supply member 17 supplies high-frequency power of a single frequency to the upper electrode 16. By supplying the high-frequency power of the single frequency, it is possible to simplify the configuration and control, as compared with a case of supplying high-frequency power of a plurality of frequencies.

The pump 101 is connected to the chamber 14 via the gas discharge path 104. The pump 101 can make the inside of the chamber 14 in a vacuum state by evacuating the inside of the chamber 14. The pump 101 can be a dry pump, for example.

### (Power Supply Member 17)

Next, a detailed configuration example of the power supply member 17 is described. FIG. 2 is a plan view of the power supply member 17 in the semiconductor manufacturing apparatus 1 according to the present embodiment.

As shown in FIG. 2, the power supply member 17 includes a conductor 171 and a plurality of capacitors C1 to C4 that are an example of passive elements. While four capacitors C1 to C4 are provided in the example of FIG. 2, the number of the capacitors is not limited to four, as long as a plurality of capacitors are provided.

The conductor 171 is arranged on the outer circumferential surface 16a of the upper electrode 16. Specifically, the conductor 171 is continuously arranged along the outer circumferential surface 16a. In other words, the conductor 171 extends along the outer circumferential surface 16a of the upper electrode 16 in form of a substantially circular arc.

More specifically, the conductor 171 branches into a plurality of branching portions 173A to 173D respectively extending from a position near an input/output end 171a to a plurality of positions on the outer circumferential surface 161a. In the example of FIG. 2, the conductor 171 branches into four branching portions 173A to 173D.

The conductor 171 has the input/output end 171a for high-frequency power, and a plurality of contacts 171b with the outer circumferential surface 161a, that is, a plurality of power supply points. The contacts 171b are respectively arranged at tips of the branching portions 173. In the example of FIG. 2, the contacts 171b are evenly spaced in a circumferential direction D2 of the outer circumferential surface 16a of the upper electrode 16. That is, the contacts 171b are respectively arranged at rotationally symmetric positions with respect to a center of the upper electrode 16. Because the positions of the respective contacts 171b are symmetric with respect to the upper electrode 16, it is easy to uniformly supply the high-frequency power to the upper electrode 16.

Each of the capacitors C1 to C4 has a first input/output end Ca and a second input/output end Cb for alternating-current power. In each of the capacitors C1 to C4, the first input/output end Ca and the second input/output end Cb are connected to mutually different positions of the conductor 171. In other words, each of the capacitors C1 to C4 is connected to the conductor 171 at both the first input/output end Ca and the second input/output end Cb. It can be also said that the capacitors C1 to C4 are connected to the conductor 171 in parallel.

Each of the capacitors C1 to C4 has a capacitance, that is, an impedance that is individually variable. Each of the capacitors C1 to C4 is a variable capacitor, for example. The variable capacitor has a fixed-side metal blade and a movable-side metal blade that are opposite to each other. The fixed-side metal blade and the movable-side metal blade have a semicircular shape that are coaxial. The movable-side metal blade can be rotated around an axis by a motor. Meanwhile, the fixed-side metal blade is fixed onto the axis. An overlapping area of the movable-side metal blade and the fixed-side metal blade is changed by rotation of the movable-side metal blade. By changing the overlapping area, the capacitance can be changed.

The capacitors C1 to C4 may be capacitors other than the variable capacitors, as long as the capacitances thereof can be changed.

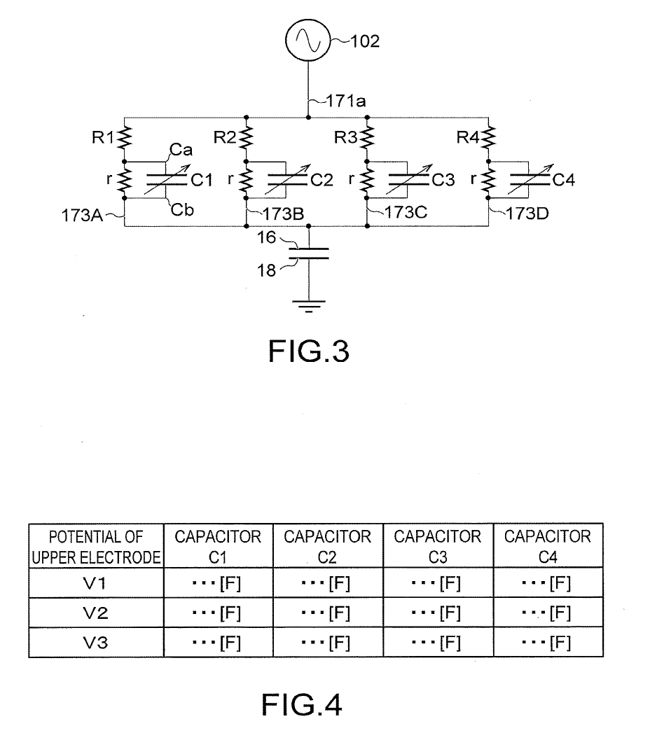

FIG. 3 is an equivalent circuit diagram of the power supply member 17 in the semiconductor manufacturing apparatus 1 according to the present embodiment. As shown in FIG. 3, the capacitors C1 to C4 are connected to resistors R1 to R4 and r formed by the branching portions 173A to 173D, respectively. Specifically, each of the capacitors C1 to C4 is connected to the resistor r formed by a corresponding one of the branching portions 173A to 173D between the first input/output end Ca and the second input/output end Cb in parallel. Also, each of the capacitors C1 to C4 is connected to a corresponding one of the resistors R1 to R4 formed by the corresponding branching portion 173A, 173B, 173C, or 173D outside that branching portion 173A, 173B, 173C, or 173D between the first input/output end Ca and the second input/output end Cb in series. In the example of FIG. 3, a resistance value of the resistor r between the first input/output end Ca and the second input/output end Cb is set to be constant at any of the branching portions 173A to 173D.

For each of the branching portions 173A to 173D, a corresponding one of the capacitors C1 to C4 is connected independently. Therefore, a combined impedance from the input/output end 171a to each contact 171b can be independently adjusted by adjusting the capacitance of each of the capacitors C1 to C4. Because the combined impedance can be independently adjusted for each contact 171b, it is possible to simply adjust the combined impedance.

The setting device 103 sets the capacitances of the respective capacitors C1 to C4. In a case where the capacitors C1 to C4 are variable capacitors, the setting device 103 may set the capacitance of each of the capacitors C1 to C4 by controlling the rotation amount of a motor that rotates the variable-side metal blade. The setting device 103 may include an arithmetic processor, such as a CPU.

### OPERATION EXAMPLE

Next, an operation example of the semiconductor manufacturing apparatus 1 having the configurations described above is described. FIG. 4 is a diagram showing a setting example of capacitances of the capacitors C1 to C4 in the semiconductor manufacturing apparatus 1 according to the present embodiment. In FIG. 4, a target potential of the upper electrode 16 and capacitances of the respective capacitors C1 to C4 corresponding to the potential of the upper electrode 16 are associated with each other. The potential of the upper electrode 16 is a value in accordance with a film-forming condition, such as a film type or a film thickness. As the potential of the upper electrode 16 in accordance with the film-forming condition, a suitable voltage may be set in advance based on an experiment or a simulation. In the example of FIG. 4, it is assumed that resistances are fixed to values corresponding to lengths of the respective branching portions 173A to 173D. However, in a case where a separate variable resistor from the conductor 171 is arranged on the conductor 171, the resistance value of the variable resistor can be also a parameter variable in accordance with the potential.

The corresponding relation in FIG. 4 is stored in a memory region of the setting device 103 as a database, for example. Data showing the corresponding relation in FIG. 4 can be stored in an external memory apparatus of the semiconductor manufacturing apparatus 1 in such a manner that the setting device 103 can read out the data.

In order to make combined impedances at the respective contacts 171b equal, for example, the capacitances of the respective capacitors C1 to C4 shown in the corresponding relation in FIG. 4 are set as follows.

The branching portion 173A corresponding to a farther contact 171b from the input/output end 171a is longer than the branching portion 173C corresponding to a closer contact 171b to the input/output end 171a. Therefore, the resistance R1 of the branching portion 173A corresponding to the farther contact 171b from the input/output end 171a is larger than the resistance R3 of the branching portion 173C corresponding to the closer contact 171b to the input/output end 171a.

In order to make the combined impedance at the farther contact 171b from the input/output end 171a and that at the closer contact 171b to the input/output end 171a equal, in the present embodiment, the capacitance C1 of the capacitor C1 corresponding to the farther contact 171b from the input/output end 171a and the capacitance C3 of the capacitor C3 corresponding to the closer contact 171b to the input/output end 171a are set to be different values, respectively.

For example, the capacitances C1 and C3 may satisfy the following relation.

$$\sqrt{{( R 1 + \frac{r}{1 + {ω}^{2} {r}^{2} C {1}^{2}} )}^{2} + {( \frac{ω {r}^{2} C 1}{1 + {ω}^{2} {r}^{2} C {1}^{2}} )}^{2}} = \sqrt{{( R 3 + \frac{r}{1 + {ω}^{2} {r}^{2} C {3}^{2}} )}^{2} + {( \frac{ω {r}^{2} C 3}{1 + {ω}^{2} {r}^{2} C {3}^{2}} )}^{2}} \qquad ( 1 )$$

In Equation (1), co represents an angular frequency of high-frequency power.

Equation (1) shows that the combined impedance at a farthest contact 171b from the input/output end 171a, formed by R1, r, and C1, and the combined impedance at a closest contact 171b to the input/output end 171a, formed by R3, r, and C3, are equal to each other. Equality relations of combined impedances similar to Equation (1) are also established between the combined impedance formed by R1, r, and C1 and a combined impedance formed by R2, r, and C2, between the combined impedance formed by R1, r, and C1 and a combined impedance formed by R4, r, and C4, and the combined impedance formed by R2, r, and C2 and the combined impedance formed by R3, r, and C3.

While Expression (1) shows a complete equality relation, the value in Expression (1) on the left side and the value on the right side may have a difference in an allowable limit therebetween. That is, in the present embodiment, the combined impedances at the respective contacts 171b that are “equal” also include the combined impedance that are “substantially equal”. Further, the expression of the combined impedance is not limited to Expression (1), but can be changed in various ways in accordance with the number of the capacitors C1 to C4 arranged on the branching portions 173A to 173D, the type of the passive element, and the like.

Assuming that the capacitances C1 to C4 in FIG. 4 are set in the above manner, the setting device 103 detects the potential in FIG. 4 associated with a film-forming condition based on an input of the film-forming condition by an input operation using a user interface or automatic detection of the film-forming condition from recipes of a process flow, for example. Simultaneously with the detection of the potential in FIG. 4, the setting device 103 detects the capacitances C1 to C4 in FIG. 4 corresponding to the detected potential.

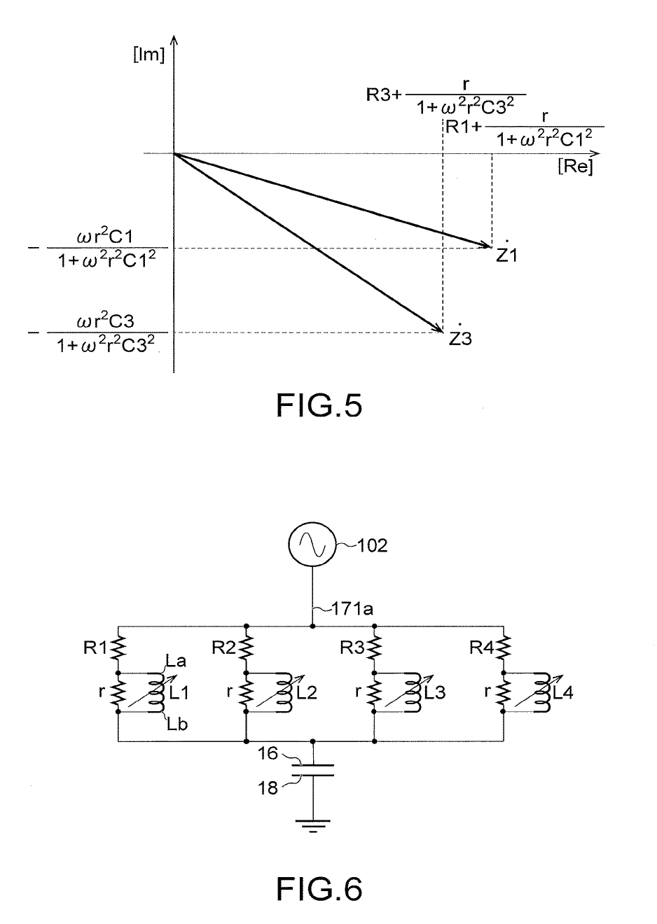

FIG. 5 is a schematic diagram showing an adjustment of a combined impedance by the semiconductor manufacturing apparatus 1 according to the present embodiment. The horizontal axis in FIG. 5 represents a real-number component, which is a resistance component, of the combined impedance from the input/output end 171a to the contact 171b. The vertical axis in FIG. 5 represents an imaginary-number component, which is a reactance component, of the combined impedance from the input/output end 171a to the contact 171b.

After detection of capacitances, the setting device 103 sets the detected capacitances C1 to C4 in the respective capacitors C1 to C4. The capacitances C1 to C4 set in the respective capacitors C1 to C4 have a corresponding relation represented by Equation (1). Therefore, by setting the capacitances C1 to C4 in the respective capacitors C1 to C4, the combined impedances at the respective contacts 171b can be made equal. For example, as shown in FIG. 5, an absolute value of a combined impedance Z1 at the farthest contact 171b from the input/output end 171a, formed by R1, r, and C1, and an absolute value of a combined impedance Z3 at the closest contact 171b to the input/output end 171a, formed by R3, r, and C3, can be the same.

In a case where the combined impedances at the respective contacts 171b cannot be adjusted, the difference of the combined impedance formed by a resistance component, that is, a difference of voltage drop between the farther contact 171b from the input/output end 171a and the closer contact 171b to the input/output end 171a becomes large. Because the difference of the combined impedances becomes large, the difference of high-frequency power supplied from the respective contacts 171b to the upper electrodes 16 becomes large. Therefore, the density of plasma generated between the upper electrode 16 and the lower electrode 18 becomes uneven, causing the amount of deposition of a film on the semiconductor substrate 2 on the lower electrode 18 to be uneven in a plane of the semiconductor substrate 2.

Further, in a case where in-plane uniformity is tried to be improved by a film-forming condition, such as a pressure inside the chamber 14 and a flow rate of gas, a trade-off of deviation of a film quality, for example, a wet etching rate and a variation amount of stress of a film with respect to heat, from a desired film quality can occur.

On the other hand, in the present embodiment, the combined impedances at the respective contacts 171b can be made equal. Therefore, it is possible to control the potential of the upper electrode 16 to be a desired value at each contact 171b and to supply high-frequency power to the upper electrode 16 uniformly. Due to this configuration, uniformity of the density of plasma generated between the upper electrode 16 and the lower electrode 18 can be improved, so that the in-plane uniformity of the thickness to be deposited on the semiconductor substrate 2 can be improved. Further, because there is no limitation on the film-forming condition in order to improve the in-plane uniformity, the trade-off of deterioration of the film quality can be prevented from occurring.

Furthermore, as described above, each of the capacitors C1 to C4 is connected to the conductor 171 at both the first input/output end Ca and the second input/output end Cb. Also, in the respective capacitors C1 to C4, the capacitances are set in such a manner that the combined impedances between the input/output end 171a and the respective contacts 171b in a case where high-frequency power of a single frequency is supplied are equal. Therefore, it is possible to control the combined impedances more simply, as compared with a case where one end of each of the capacitors C1 to C4 is grounded and the combined impedances between the input/output end 171a and the respective contacts 171b are made equal by using high-frequency power of a plurality of frequencies.

Therefore, according to the present embodiment, uniform power supply, that is, symmetrical power supply can be achieved at the respective contacts 171b by means of the power supply member 17. Therefore, in-plane uniformity can be improved.

### (Modifications)

Next, as a first modification of the present embodiment, there is described an example in which an inductor having a variable inductance is provided as a passive element. In the first modification, constituent elements corresponding to those shown in FIGS. 1 to 5 are denoted by like reference characters, and redundant explanations thereof will be omitted. FIG. 6 is an equivalent circuit diagram of the power supply member 17 in the semiconductor manufacturing apparatus 1 according to the first modification of the present embodiment.

As shown in FIG. 6, the power supply member 17 according to the first modification is different from the configurations of FIGS. 1 to 5, and includes a plurality of inductors L1 to L4 arranged on the respective branching portions 173A to 173D in place of the capacitors C1 to C4. The inductors L1 to L4 each have a first input/output end La and a second input/output end Lb for alternating-current power. The first input/output end La and the second input/output end Lb of each of the inductors L1 to L4 are connected to different positions of the conductor 171. An inductance of each of the inductors L1 to L4 can be changed individually. The inductors L1 to L4 are variable coils, for example. The variable coil may have a configuration in which a core inserted in a winding is slid so that the position of the core with respect to the winding is changed. In the variable coil having this configuration, the permeability of the core can be changed by sliding the position of the core, so that the inductance can be changed. The inductors L1 to L4 may be inductors other than the variable coils, as long as their inductances can be changed.

In order to make the combined impedances equal, an inductance L1 of the inductor L1 corresponding to the farthest contact 171b from the input/output end 171a and an inductance L3 of the inductor L3 corresponding to the closest contact 171b to the input/output end 171a satisfy the following relation, for example.

$$\sqrt{{( R 1 + \frac{{ω}^{2} r L {1}^{2}}{{r}^{2} + {ω}^{2} L {1}^{2}} )}^{2} + {( \frac{ω {r}^{2} L 1}{{r}^{2} + {ω}^{2} L {1}^{2}} )}^{2}} = \sqrt{{( R 3 + \frac{{ω}^{2} r L {3}^{2}}{{r}^{2} + {ω}^{2} L {3}^{2}} )}^{2} + {( \frac{ω {r}^{2} L 3}{{r}^{2} + {ω}^{2} L {3}^{2}} )}^{2}} \qquad ( 2 )$$

Equality relations of the combined impedances similar to Expression (2) are also established between a combined impedance formed by R1, r, and Li, and a combined impedance formed by R2, r, and L2, between the combined impedance formed by R1, r, and C1 and a combined impedance formed by R4, r, and C4, and between the combined impedance formed by R2, r, and L2 and a combined impedance formed by R3, 3, and L3.

While Expression (2) shows a complete equality relation, the value in Expression (2) on the left side and the value on the right side may have a difference in an allowable limit therebetween. Further, an expression of the combined impedances is not limited to Expression (2), but can be changed in various ways in accordance with the number of the inductors L1 to L4 arranged on the branching portions 173A to 173D and the like.

By setting the inductances having the corresponding relation shown in Expression (2) in the inductors L1 to L4, it is possible to make the combined impedances at the respective contacts 171b equal.

Therefore, also in the first modification, the power supply member 17 can perform uniform power supply at the respective contacts 171b. Due to this configuration, in-plane uniformity can be improved.

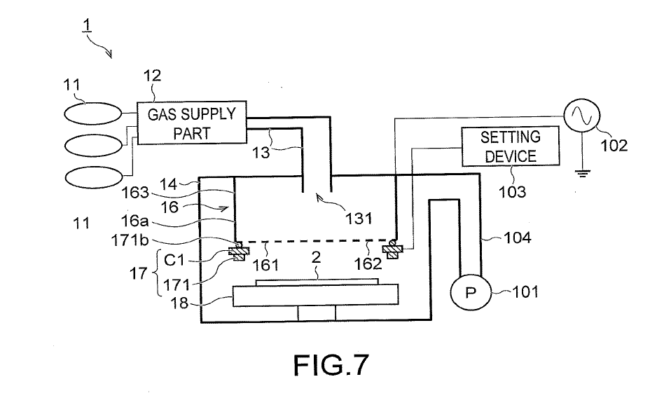

FIG. 7 is a schematic sectional view showing a semiconductor manufacturing apparatus according to a second modification of the present embodiment. In the embodiment described above, the conductor 171 is continuously arranged along the outer circumferential surface 16a of the upper electrode 16, and the contacts 171b are in contact with the outer circumferential surface 16a.

In connection thereto, as shown in FIG. 7, the conductor 171 may be continuously arranged along a peripheral edge 16b of the upper electrode 16, and the contacts 171b may be in contact with the peripheral edge 16b.

Also in the second modification, it is possible to achieve uniform power supply at the respective contacts 171b of the power supply member 17 by making the impedances at the respective contacts 171b equal, similarly to the embodiment described above. That is, also in the second modification, in-plane uniformity can be improved.

In the embodiment described above, passive elements of the same type are arranged on the branching portions 173A to 173D one by one. However, the number and types of the passive elements arranged on the respective branching portions 173A to 173D can be different. Also, different types of passive elements can be arranged on one of the branching portions 173A to 173D. For example, a capacitor and an inductor can be arranged on one of the branching portions 173A to 173D.

Further, in a series of processes in which a film-forming condition is changed, the setting device 103 can change the impedance of a passive element every time the film-forming condition is changed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A Semiconductor manufacturing apparatus comprising:
a reactor capable of accommodating a semiconductor substrate therein;
a first electrode arranged in the reactor and can place the semiconductor substrate thereon;
a second electrode opposed to the first electrode in the reactor; and
a first member supplying alternating-current power to the second electrode, and including a conductor that is arranged on an outer circumferential surface or at an outer peripheral edge of the second electrode and has an input/output end for the alternating-current power and a plurality of contacts with respect to the outer circumferential surface or the outer peripheral edge, and a plurality of passive elements each having a first input/output end and a second input/output end for the alternating-current power, where the first input/output end and the second input/output end are connected to different positions of the conductor.

2. The apparatus of claim 1, wherein the passive elements each have an impedance that is individually variable.

3. The apparatus of claim 1, wherein the first member supplies alternating-current power of a single frequency to the second electrode in order to generate plasma between the first electrode and the second electrode.

4. The apparatus of claim 2, wherein the first member supplies alternating-current power of a single frequency to the second electrode in order to generate plasma between the first electrode and the second electrode.

5. The apparatus of claim 2, wherein the passive elements include a capacitor of which a capacitance is variable.

6. The apparatus of claim 4, wherein the passive elements include a capacitor of which a capacitance is variable.

7. The apparatus of claim 2, wherein the passive elements include an inductor of which an inductance is variable.

8. The apparatus of claim 4, wherein the passive elements include an inductor of which an inductance is variable.

9. The apparatus of claim 2, further comprising a setting device that sets impedances of the passive elements in such a manner that a combined impedance between the input/output end and a first one of the contacts and a combined impedance between the input/output end and a second one of the contacts are equal.

10. The apparatus of claim 4, further comprising a setting device that sets impedances of the passive elements in such a manner that a combined impedance between the input/output end and a first one of the contacts and a combined impedance between the input/output end and a second one of the contacts are equal.

11. The apparatus of claim 5, further comprising a setting device that sets impedances of the passive elements in such a manner that a combined impedance between the input/output end and a first one of the contacts and a combined impedance between the input/output end and a second one of the contacts are equal.

12. The apparatus of claim 6, further comprising a setting device that sets impedances of the passive elements in such a manner that a combined impedance between the input/output end and a first one of the contacts and a combined impedance between the input/output end and a second one of the contacts are equal.

13. The apparatus of claim 7, further comprising a setting device that sets impedances of the passive elements in such a manner that a combined impedance between the input/output end and a first one of the contacts and a combined impedance between the input/output end and a second one of the contacts are equal.

14. The apparatus of claim 8, further comprising a setting device that sets impedances of the passive elements in such a manner that a combined impedance between the input/output end and a first one of the contacts and a combined impedance between the input/output end and a second one of the contacts are equal.

15. The apparatus of claim 1, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.

16. The apparatus of claim 2, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.

17. The apparatus of claim 3, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.

18. The apparatus of claim 5, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.

19. The apparatus of claim 7, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.

20. The apparatus of claim 9, wherein
the conductor branches into a plurality of branching portions extending from a position near the input/output end to a plurality of positions on the outer circumferential surface or the outer peripheral edge, respectively,
the contacts are arranged at tips of the branching portions, respectively, and
the passive elements are arranged on the branching portions, respectively.
